(19) United States
(12) Patent Application Publication
(10) Pub. No.: US 2024/0324406 A1
(43) Pub. Date: Sep. 26, 2024

(54) DISPLAY APPARATUS

(71) Applicant: Samsung Display Co., Ltd., Yongin-si (KR)

(72) Inventors: Jiphyo Hong, Yongin-si (KR); Seongsik Ahn, Yongin-si (KR)

(21) Appl. No.: 18/500,866

(22) Filed: Nov. 2, 2023

(30) Foreign Application Priority Data
Mar. 24, 2023 (KR) 10-2023-0038994
May 31, 2023 (KR) 10-2023-0070409

(51) Int. Cl. H10K 59/80; H10K 59/40

(52) U.S. Cl. CPC H10K 59/873; H10K 59/40; H10K 59/8794; H10K 2102/311

(57) ABSTRACT

A display apparatus includes: a cover panel; a display panel on the cover panel; and a cover window on the display panel. The display panel includes: a substrate having a first surface facing the cover panel, and a second surface opposite to the first surface, the substrate including: a display area including a plurality of pixels; a first peripheral area outside the display area, and overlapping with the cover panel; and a second peripheral area outside the first peripheral area; a display layer on the second surface of the substrate, and including a pixel circuit; and a thin-film encapsulation layer on the display layer. The first surface of the substrate includes: a 1-1 surface parallel to the second surface; and a 1-2 surface inclined from the 1-1 surface and located at least in the second peripheral area.

### CROSS-REFERENCE TO RELATED APPLICATIONS

The present application claims priority to and the benefit of Korean Patent Application No. 10-2023-0038994, filed on Mar. 24, 2023, and Korean Patent Application No. 10-2023-0070409, filed on May 31, 2023, in the Korean Intellectual Property Office, the entire content of all of which are incorporated by reference herein.

### BACKGROUND

### 1. Field

One or more embodiments of the present disclosure relate to a display apparatus, and more particularly, to a display apparatus including a portion that is bendable.

### 2. Description of Related Art

Recently, electronic devices have been widely used. Various kinds of electronic devices, such as mobile electronic devices and fixed-type electronic devices, have been used. Such electronic devices include display apparatuses capable of providing visual information, such as images or videos, to users to support various functions.

Recently, according to the decrease in sizes of components for driving the display apparatuses, the importance of the display apparatuses in electronic devices have increased, and a structure that may be bent to a certain degree in a flat state or folded with reference to an axis has been developed.

The above information disclosed in this Background section is for enhancement of understanding of the background of the present disclosure, and therefore, it may contain information that does not constitute prior art.

### SUMMARY

Generally, a display apparatus includes a display panel. The display panel includes a display area for displaying images, and a peripheral area that is a non-display area adjacent to the display area. With respect to the display panel, by bending at least a portion of the peripheral area, visibility from various angles may be improved, and/or an area of the non-display area may be reduced.

One or more embodiments of the present disclosure are directed to a display apparatus having improved reliability by preventing or substantially preventing damage that may be caused by external pressure. However, the aspects and features of the present disclosure are not limited thereto.

Additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a cover panel; a display panel on the cover panel; and a cover window on the display panel. The display panel includes: a substrate having a first surface facing the cover panel, and a second surface opposite to the first surface, the substrate including: a display area including a plurality of pixels; a first peripheral area outside the display area, and overlapping with the cover panel; and a second peripheral area outside the first peripheral area; a display layer on the second surface of the substrate, and including a pixel circuit; and a thin-film encapsulation layer on the display layer. The first surface of the substrate includes: a 1-1 surface parallel to the second surface; and a 1-2 surface inclined from the 1-1 surface and located at least in the second peripheral area.

In an embodiment, a width of the substrate may be greater than a width of the cover panel.

In an embodiment, the second peripheral area may not overlap with the cover panel.

In an embodiment, in the second peripheral area, a distance between the first surface and the second surface of the substrate may decrease in a direction from the first peripheral area toward the second peripheral area.

In an embodiment, the 1-1 surface of the substrate may be located in the display area and the first peripheral area.

In an embodiment, the 1-2 surface of the substrate may be located in at least a portion of the first peripheral area and the second peripheral area.

In an embodiment, in at least the portion of the first peripheral area, a distance between the first surface and the second surface of the substrate may decrease in a direction from the first peripheral area toward the second peripheral area.

In an embodiment, the 1-1 surface of the substrate may be located in the display area.

In an embodiment, in at least the portion of the first peripheral area, a distance between the first surface and the second surface of the substrate may decrease in a direction from the first peripheral area toward the second peripheral area, and in another portion of the first peripheral area, the distance between the first surface and the second surface of the substrate may be constant.

In an embodiment, the display apparatus may further include an organic layer on the 1-2 surface of the substrate.

In an embodiment, the organic layer may include a material having a rigidity less than a rigidity of the substrate.

In an embodiment, a width of the substrate may be less than a width of the cover window.

In an embodiment, the cover panel may include a heat-radiating layer.

In an embodiment, the display apparatus may further include: an optical function layer on the display panel; and a touch sensor layer on the optical function layer.

According to one or more embodiments of the present disclosure, a display apparatus includes: a cover panel; and a display panel on the cover panel. The display panel includes: a substrate having a first surface facing the cover panel, and a second surface opposite to the first surface, the substrate including: a display area including a plurality of pixels; and a peripheral area outside the display area; a display layer on the second surface of the substrate, and including a pixel circuit; and a thin-film encapsulation layer on the display layer. A width of the substrate is greater than a width of the cover panel, and at least a portion of the first surface of the substrate has a slope in the peripheral area.

In an embodiment, the peripheral area may include: a first peripheral area overlapping with the cover panel; and a second peripheral area outside the first peripheral area. The slope of the substrate may be located in at least the second peripheral area.

In an embodiment, the slope of the substrate may be located in the first peripheral area, and may extend to the second peripheral area.

In an embodiment, the display apparatus may further include an organic layer on the slope of the substrate.

In an embodiment, the organic layer may include a material having a rigidity less than a rigidity of the substrate.

According to one or more embodiments of the present disclosure, a display apparatus includes: a cover panel; a display panel on the cover panel; and a cover window on the display panel. The display panel includes: a substrate including: a display area including a plurality of pixels; a first peripheral area outside the display area, and overlapping with the cover panel; and a second peripheral area outside the first peripheral area; a display layer on the substrate, and including a pixel circuit; and a thin-film encapsulation layer on the display layer. In the second peripheral area, a thickness of the substrate decreases in a direction from the first peripheral area toward the second peripheral area.

In an embodiment, the substrate may include a first surface facing the cover panel, and a second surface opposite the first surface, and in the second peripheral area, the first surface of the substrate may be inclined with respect to the second surface.

In an embodiment, in the first peripheral area, a thickness of the substrate may be constant.

In an embodiment, in at least a portion of the first peripheral area, a thickness of the substrate may decrease in the direction from the first peripheral area toward the second peripheral area.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view schematically illustrating a display apparatus according to an embodiment;

FIG. 2 is a cross-sectional view schematically illustrating a display apparatus according to an embodiment;

FIG. 3 is a cross-sectional view schematically illustrating a display apparatus according to an embodiment;

FIG. 4 is a cross-sectional view schematically illustrating a display panel according to an embodiment;

FIG. 5A is an enlarged view of the area A shown in FIG. 3, according to an embodiment;

FIG. 5B is an enlarged view of the area A shown in FIG. 3, according to an embodiment;

FIG. 6A is an enlarged view of the area A shown in FIG. 3, according to an embodiment;

FIG. 6B is an enlarged view of the area A shown in FIG. 3, according to an embodiment; and

FIG. 7 is an enlarged view of the area A shown in FIG. 3, according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

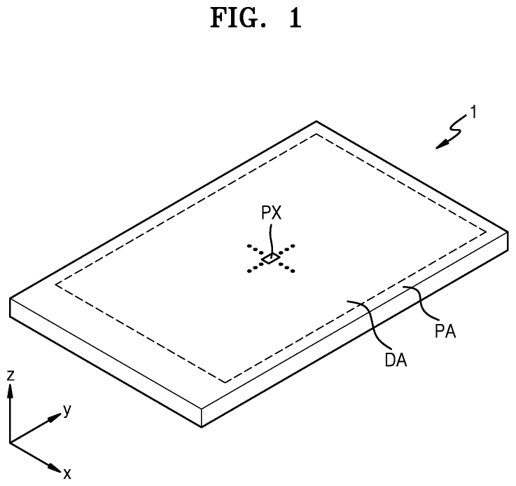

FIG. 1 is a perspective view schematically illustrating a display apparatus 1 according to an embodiment.

Referring to FIG. 1, the display apparatus 1 is an apparatus configured to display videos and/or still images. The display apparatus 1 may be used as a display screen of various suitable products, such as televisions, notebook computers, monitors, billboard charts, Internet of Things (IoT) devices, and the like, as well as a display screen for various suitable portable electronic devices, such as mobile phones, smart phones, tablet personal computers (PC), mobile communication terminals, electronic organizers, electronic books, portable multimedia players (PMP), navigation devices, ultra mobile PCs (UMPC), and the like. In addition, the display apparatus 1 according to an embodiment may be used for wearable devices, such as smart watches, watch phones, and head mounted displays (HMD). As another example, the display apparatus 1 according to an embodiment may be used as a center information display (CID) arranged on a dashboard or center fascia of a vehicle, a room mirror display substituting a side mirror of the vehicle, or a display arranged on a back surface of a front seat as entertainment for passengers in rear seats of the vehicle.

As shown in FIG. 1, the shape of the display apparatus 1 may be rectangular or approximately rectangular. For example, the display apparatus 1 may have a plane shape that is generally rectangular, and having a short side extending in a first direction (e.g., the x direction or −x direction) and a long side extending in a second direction (e.g., the y direction or −y direction), as shown in FIG. 1. In an embodiment, a point (e.g., a corner) at which the short side extending in the first direction (e.g., the x direction or −x direction) meets the long side extending in the second direction (e.g., the y direction or −y direction) may have a right-angled shape, or a rounded shape having a suitable curvature (e.g., a certain or predetermined curvature). However, the plane shape of the display apparatus 1 is not limited to the rectangle, and the display apparatus 1 may have various suitable shapes, such as another polygon, a circle, or an oval.

The display apparatus 1 may include a display area DA and a peripheral area PA. The display area DA may be configured to display images. A plurality of pixels PX may be arranged in the display area DA. The display apparatus 1 may be configured to provide the images using light emitted from the plurality of pixels PX. Each of the plurality of pixels PX may be configured to emit light using a display element. In an embodiment, each of the plurality of pixels PX may be configured to emit red, green, or blue light. In an embodiment, each of the plurality of pixels PX may be configured to emit red, green, blue, or white light.

The peripheral area PA, which does not provide images, may include a non-display area. The peripheral area PA may at least partially surround (e.g., around a periphery of) the display area DA. For example, the peripheral area PA may entirely surround (e.g., around a periphery of) the display area DA. A driver configured to provide electrical signals to the plurality of pixels PX or a power wiring configured to provide power to the plurality of pixels PX may be arranged in the peripheral area PA. For example, a scan driver configured to apply scan signals to the plurality of pixels PX may be arranged in the peripheral area PA. In addition, a data driver configured to apply data signals to the plurality of pixels PX may be arranged in the peripheral area PA.

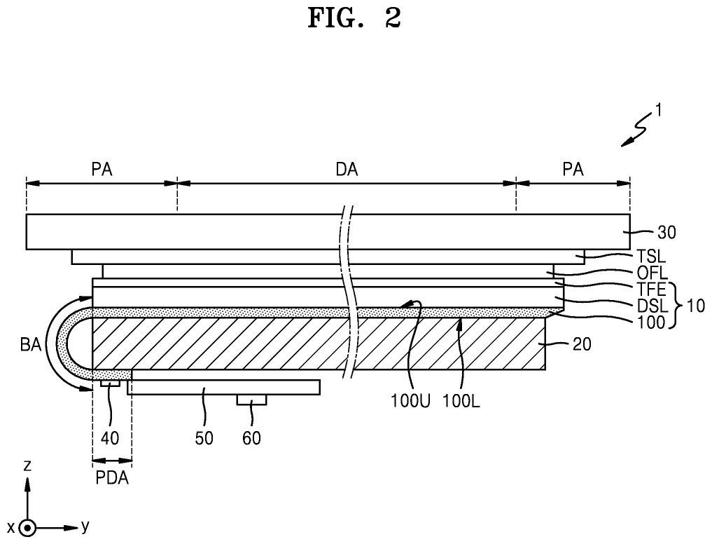

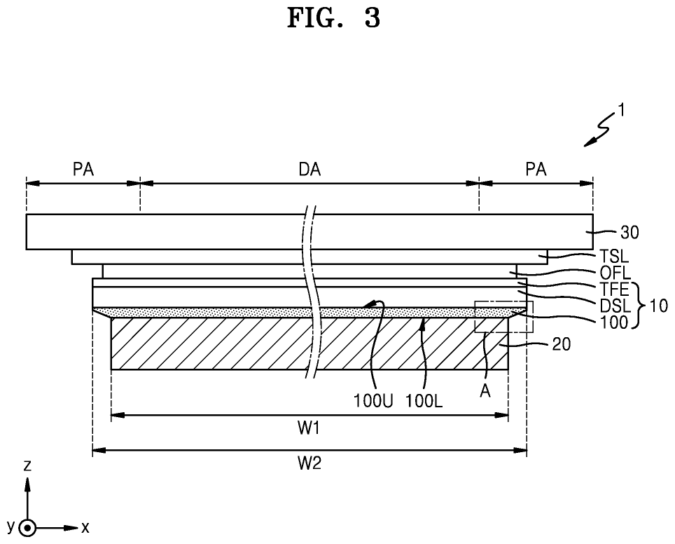

FIG. 2 is a cross-sectional view schematically illustrating the display apparatus 1 according to an embodiment. FIG. 3 is a cross-sectional view schematically illustrating the display apparatus 1 according to an embodiment. FIG. 2 may be a cross-sectional view of the display apparatus 1 along the first direction (e.g., the y direction), and FIG. 3 may be a cross-sectional view of the display apparatus 1 along the second direction (e.g., the x direction) crossing the first direction.

Referring to FIGS. 2 and 3, the display apparatus 1 may include a display panel 10, a cover panel 20, and a cover window 30. In an embodiment, as shown in FIG. 2, the display apparatus 1 may further include a display driver 40, a display circuit board 50, and a touch sensor driver 60.

The display panel 10 may be configured to display information processed by the display apparatus 1. For example, the display panel 10 may be configured to display execution screen information of an application driven by the display apparatus 1, or user interface (UI) information and graphic user interface (GUI) information according to the execution screen information.

The display panel 10 may include a display element. For example, the display panel 10 may include an organic light-emitting display panel in which organic light-emitting diodes are used, a micro light-emitting diode display panel in which micro LEDs are used, a quantum-dot light-emitting display panel in which quantum-dot light-emitting diodes each including a quantum-dot emission layer are used, or an inorganic light-emitting display panel in which inorganic light-emitting diodes including inorganic semiconductors are used. Hereinafter, for convenience, a case in which the display panel 10 includes the organic light-emitting display panel in which the organic light-emitting diodes are used will be described in more detail.

The display panel 10 may include a substrate 100, and a multiple-layered film disposed on the substrate 100. In an embodiment, the display panel 10 may include the substrate 100, a display layer DSL, and a thin-film encapsulation layer TFE. In this case, the display area DA and the peripheral area PA may be defined on the substrate 100 and/or the multiple-layered film. For example, it may be understood that the display panel 10 includes the display area DA and the peripheral area PA. As shown in FIG. 2, the peripheral area PA may include a pad area PDA and a bending area BA.

The substrate 100 may be disposed on the cover panel 20. The substrate 100 may include a first surface 100L facing the cover panel 20, and a second surface 100U opposite to the first surface 100L. The second surface 100U of the substrate 100 may face the display layer DSL. In an embodiment, the substrate 100 may have a shape in which a thickness (e.g., in the z direction) of the substrate 100, in at least a portion of the peripheral area PA, decreases in a direction (e.g., the x direction or the y direction) from the display area DA toward the peripheral area PA. In an embodiment, the first surface 100L of the substrate 100 may include a slope having a gradient in at least a portion of the peripheral area PA. The shape of the substrate 100 in which the thickness of at least the portion of the substrate 100 decreases may be formed, for example, through an etching process. In an embodiment, the substrate 100 may include glass. As used in the present specification, the thickness of the substrate 100 may be defined as a vertical thickness in a direction (e.g., the z direction) perpendicular to or substantially perpendicular to the second surface 100U (e.g., the top surface) of the substrate 100.

The substrate 100 may be bent in the bending area BA. In this case, at least some portions of the bottom surface of the substrate 100 may face each other, and the pad area PDA of the substrate 100 may be at a lower portion compared with other portions of the substrate 100. Accordingly, an area of the peripheral area PA that may be recognized by the user may be reduced. Although FIG. 2 illustrates that only the substrate 100 is bent, in another embodiment, at least a portion of the display layer DSL and at least a portion of the thin-film encapsulation layer TFE may also be disposed in the bending area BA and the pad area PDA. In this case, at least the portion of the display layer DSL and at least the portion of the thin-film encapsulation layer TFE may also be bent in the bending area BA.

The display layer DSL may be disposed on the substrate 100. The display layer DSL may include pixel circuits and display elements. In this case, the pixel circuits may be connected to the display elements, respectively. The pixel circuit may include a thin-film transistor and a storage capacitor. Accordingly, the display layer DSL may include a plurality of display elements, a plurality of thin-film transistors, and a plurality of storage capacitors. In addition, the display layer DSL may further include insulating layers disposed among the aforementioned components.

The thin-film encapsulation layer TFE may be disposed on the display layer DSL. The thin-film encapsulation layer TFE may be disposed on the display elements to cover the display elements. In an embodiment, the thin-film encapsulation layer TFE may include at least one inorganic encapsulation layer, and at least one organic encapsulation layer. The at least one inorganic encapsulation layer may include one or more inorganic materials from among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). The at least one organic encapsulation layer may include a polymer-based material. The polymer-based material may include an acryl-based resin, an epoxy-based resin, polyimide, polyethylene, and/or the like. In an embodiment, the at least one organic encapsulation layer may include acrylate.

In an embodiment, an optical function layer OFL and a touch sensor layer TSL may be disposed on the display panel 10. In an embodiment, the optical function layer OFL may be disposed on the thin-film encapsulation layer TFE, and the touch sensor layer TSL may be disposed on the optical function layer OFL. However, the stacking order of the optical function layer OFL and the touch sensor layer TSL may be variously modified as needed or desired. For example, in another embodiment, the touch sensor layer TSL may be disposed on the thin-film encapsulation layer TFE, and the optical function layer OFL may be disposed on the touch sensor layer TSL. In an embodiment, the display apparatus 1 may further include an adhesive layer disposed between the optical function layer OFL and the thin-film encapsulation layer TFE, and/or between the optical function layer OFL and the touch sensor layer TSL.

The optical function layer OFL may reduce a reflectance of light (e.g., external light) incident from outside of the display apparatus 1, and/or may improve a color purity of light emitted from the display apparatus 1. In an embodiment, the optical function layer OFL may include a retarder and a polarizer. The retarder may include a film type or liquid-crystal coating type, and may include a λ/2 retarder and/or a λ/4 retarder. The polarizer may also include a film type or a liquid-crystal coating type. A film-type polarizer may include a stretched-type synthetic resin film, and a liquid-crystal coating type polarizer may include liquid crystals arranged in a suitable arrangement (e.g., a certain or predetermined arrangement). The retarder and the polarizer may each further include a protection film.

In another embodiment, the optical function layer OFL may include a black matrix and color filters. The color filters may be arranged in consideration of the colors of light emitted from each of the pixels PX of the display apparatus 1. Each of the color filters may include a red, green, or blue pigment or dye. As another example, in addition to the pigment or dye, each of the color filters may further include quantum dots. As another example, some of the color filters may not include the aforementioned pigment or dye, and may include scattering particles such as titanium oxide particles.

In another embodiment, the optical function layer OFL may include a destructive interference structure. The destructive interference structure may include a first reflective layer and a second reflective layer disposed at (e.g., in or on) different layers from each other. First reflected light and second reflected light reflected by the first reflective layer and the second reflective layer, respectively, may undergo destructive interference, and accordingly, a reflectance of the external light may be reduced.

The touch sensor layer TSL may be configured to sense coordinate information according to foreign inputs, for example, such as touch events. The touch sensor layer TSL may include a sensor electrode, and touch wirings connected to the sensor electrode. The touch sensor layer TSL may be configured to sense the foreign inputs in a self-capacitance method or a mutual capacitance method.

The cover panel 20 may be disposed under the display panel 10. The cover panel 20 may also be disposed under the substrate 100. As a width of the substrate 100 is greater than a width of the cover panel 20, at least a portion of the substrate 100 may not overlap with the cover panel 20, and thus, may be exposed from (e.g., out of) the cover panel 20. For example, as shown in FIG. 3, a width W2 in the second direction (e.g., the x direction) of the substrate 100 may be greater than a width W1 in the second direction (e.g., the x direction) of the cover panel 20. In an embodiment, the width W2 of the substrate 100 may be smaller than a width (e.g., in the second direction) of the cover window 30. The width W2 of the substrate 100 and the width W1 of the cover panel 20 may each be defined as a greatest width (e.g., in the second direction) thereof.

In an embodiment, the cover panel 20 may include a heat-radiating layer configured to radiate heat generated from the display panel 10, and an impact absorption layer for absorbing physical impacts applied to the display panel 10. The heat-radiating layer may have a form of a thin plate. The heat-radiating layer may include a single layer, or multiple layers in which a plurality of function layers are stacked. The impact absorption layer may have an elasticity. For example, the impact absorption layer may include a polymer resin, such as polyurethane, polycarbonate, polypropylene, polyethylene, and/or the like, or may include an elastic material (e.g., rubber or a sponge obtained through foaming plastic on a urethane-based material or an acryl-based material).

The cover window 30 may be disposed above the display panel 10. In an embodiment, the cover window 30 may be disposed on the touch sensor layer TSL. The cover window 30 may cover the display panel 10, the optical function layer OFL, and the touch sensor layer TSL. In an embodiment, the cover window 30 may include a flexible window. The cover window 30 may be easily bent due to external forces and may protect the display panel 10, without the occurrence of cracks and the like therein. The cover window 30 may include at least one of glass, sapphire, or plastic. The cover window 30 may be formed of, for example, ultra-thin glass or a colorless polyimide. In an embodiment, the cover window 30 may have a structure in which a flexible polymer layer is disposed on a surface of a glass substrate, or may only include a polymer layer.

As shown in FIG. 2, the display driver 40 may be arranged in the pad area PDA. The display driver 40 may be configured to receive control signals and power voltages, and may generate and output signals and voltages for driving the display panel 10. The display driver 40 may include (e.g., may be implemented as) an integrated circuit (IC).

The display circuit board 50 may be electrically connected to the display panel 10. For example, the display circuit board 50 may be electrically connected to the pad area PDA of the substrate 100 through an anisotropic conductive film.

The display circuit board 50 may include a flexible printed circuit board (FPCB) that is bendable, or a rigid printed circuit board (PCB) that is rigid and not easily bent. As another example, as needed or desired, the display circuit board 50 may include a complex printed circuit board including both a PCB and an FPCB.

The touch sensor driver 60 may be disposed on the display circuit board 50. The touch sensor driver 60 may include (e.g., may be implemented as) an integrated circuit. The touch sensor driver 60 may be attached onto the display circuit board 50. The touch sensor driver 60 may be electrically connected to the sensor electrodes of the touch sensor layer TSL through the display circuit board 50.

A power supply unit (e.g., a power supply) may be additionally arranged on the display circuit board 50. The power supply unit may be configured to supply a driving voltage for driving the pixels PX of the display panel 10 and the display driver 40.

In an embodiment, the display apparatus 1 may further include a protective film attached to the bottom surface of the substrate 100. For example, the protective film may be disposed between the first surface 100L of the substrate 100 and the cover panel 20. In this case, the protective film may be attached to a portion out of the bending area BA of the substrate 100. For example, a portion of the protective film may be attached to the bottom surface of the substrate 100 to correspond to the display area DA, and another portion of the protective film may be attached to the bottom surface of the substrate 100 to correspond to the pad area PDA.

The thicknesses of the cover panel 20, the cover window 30, the substrate 100, the display layer DSL, and the thin-film encapsulation layer TFE described above with reference to FIGS. 2 and 3 are provided as examples, and are not limited thereto or to those illustrated in the drawings.

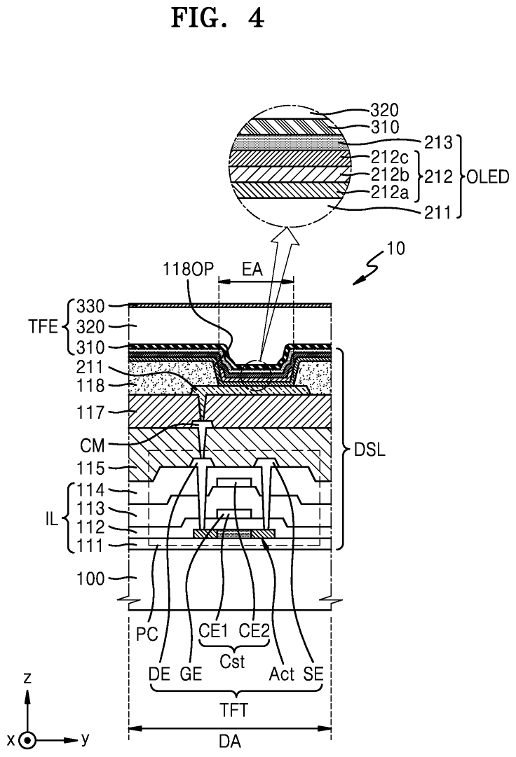

FIG. 4 is a cross-sectional view schematically illustrating the display panel 10 according to an embodiment. FIG. 4 may illustrate a portion of the cross-sectional view of the display panel 10 arranged in the display area DA.

Referring to FIG. 4, in the display area DA, the display panel 10 may include the substrate 100, the display layer DSL, and the thin-film encapsulation layer TFE.

The display layer DSL may be disposed on the substrate 100. The display layer DSL may include an inorganic insulating layer IL, a pixel circuit PC, a first planarization layer 115, a second planarization layer 117, and an organic light-emitting diode OLED. The inorganic insulating layer IL may include a buffer layer 111, a first gate insulating layer 112, a second gate insulating layer 113, and an interlayer insulating layer 114. The pixel circuit PC may include a thin-film transistor TFT and a storage capacitor Cst.

The buffer layer 111 may be disposed on the substrate 100. The buffer layer 111 may include an inorganic insulating layer, such as silicon nitride (SiNₓ), silicon oxynitride (SiON), and/or silicon oxide (SiO₂), and may have a single layer or multiple layers including one or more of the aforementioned inorganic insulating materials.

The thin-film transistor TFT may include a semiconductor layer Act, and the semiconductor layer Act may be disposed on the buffer layer 111. The semiconductor layer Act may include polysilicon. As another example, the semiconductor layer Act may include amorphous silicon, an oxide semiconductor, or an organic semiconductor. The semiconductor layer Act may include a channel area, and may also include a drain area and a source area arranged at two sides (e.g., opposite sides), respectively, of the channel area. A gate electrode GE may overlap with the channel area.

The gate electrode GE may include a low-resistance metal material. The gate electrode may include a conductive material including molybdenum (Mo), aluminum (Al), copper (Cu), and/or titanium (Ti), and may include multiple layers or a single layer including one or more of the aforementioned materials.

The first gate insulating layer 112 may be disposed between the semiconductor layer Act and the gate electrode GE, and may include an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO).

The second gate insulating layer 113 may be provided to cover the gate electrode GE. Like the first gate insulating layer 112, the second gate insulating layer 113 may include an inorganic insulating material, such as SiO₂, SiNₓ, SiON, Al₂O₃, TiO₂, Ta₂O₅, HfO₂, or ZnO.

An upper electrode CE2 of the storage capacitor Cst may be disposed on the second gate insulating layer 113. The upper electrode CE2 may overlap with the gate electrode GE thereunder. In this case, the gate electrode GE and the upper electrode CE2, which overlap with each other with the second gate insulating layer 113 therebetween, may together form the storage capacitor Cst. In other words, the gate electrode GE may function as a lower electrode CE1 of the storage capacitor Cst.

As described above, in some embodiments, the storage capacitor Cst and the thin-film transistor TFT may overlap with each other. In some embodiments, the storage capacitor Cst may not overlap with the thin-film transistor TFT.

The upper electrode CE2 may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multiple layers including one or more of the aforementioned materials.

The interlayer insulating layer 114 may cover the upper electrode CE2. The interlayer insulating layer 114 may include SiO₂, SiNₓ, SiON, Al₂O₃, TiO₂, Ta₂O₅, HfO₂, or ZnO. The interlayer insulating layer 114 may include a single layer or multiple layers including one or more of the aforementioned inorganic insulating materials.

Each of a drain electrode DE and a source electrode SE may be disposed on the interlayer insulating layer 114. Each of the drain electrode DE and the source electrode SE may include a highly conductive material. Each of the drain electrode DE and the source electrode SE may include a conductive material including Mo, Al, Cu, Ti, and/or the like, and may have multiple layers or a single layer including one or more of the aforementioned materials. In an embodiment, each of the drain electrode DE and the source electrode SE may have a multi-layered structure including Ti/Al/Ti.

The first planarization layer 115 may be arranged to cover the drain electrode DE and the source electrode SE. The first planarization layer 115 may include an organic insulating layer. The first planarization layer 115 may include an organic insulating material, for example, such as a general-purpose polymer (e.g., polymethylmethacrylate (PMMA) or polystyrene (PS)), a polymer derivative having a phenol-based group, an acryl-based polymer, an imide-based polymer, an arylether-based polymer, an amide-based polymer, a fluoride-based polymer, a p-xylene based polymer, a vinylalcohol-based polymer, and/or suitable blends thereof.

A connection electrode CM may be disposed on the first planarization layer 115. The connection electrode CM may be connected to the drain electrode DE or the source electrode SE through a contact hole in (e.g., penetrating) the first planarization layer 115. The connection electrode CM may include a highly conductive material. The connection electrode CM may include a conductive material including Mo, Al, Cu, Ti, and/or the like, and may have multiple layers or a single layer including one or more of the aforementioned materials. In an embodiment, the connection electrode CM may have a multi-layered structure including Ti/Al/Ti.

The second planarization layer 117 may be arranged to cover the connection electrode CM. The second planarization layer 117 may include an organic insulating layer. The second planarization layer 117 may include an organic insulating material, for example, such as a general-purpose polymer (e.g., PMMA or PS), a polymer derivative having a phenol-based group, an acryl-based polymer, an imide-based polymer, an arylether-based polymer, an amide-based polymer, a fluoride-based polymer, a p-xylene based polymer, a vinylalcohol-based polymer, and/or suitable blends thereof.

The organic light-emitting diode OLED may be disposed on the second planarization layer 117. The organic light-emitting diode OLED may be configured to emit red, green, or blue light, or to emit red, green, blue, or white light. The organic light-emitting diode OLED may include a pixel electrode 211, an intermediate layer 212, and a counter electrode 213.

The pixel electrode 211 may be disposed on the second planarization layer 117. The pixel electrode 211 may be electrically connected to the connection electrode CM through a contact hole in (e.g., penetrating) the second planarization layer 117. The pixel electrode 211 may include a conductive oxide material, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective film including Ag, Mg, Al, Pt, Pd, Au, Ni, Nd, Ir, Cr, or suitable compounds thereof. In another embodiment, the pixel electrode 211 may further include a film including ITO, IZO, ZnO, or In₂O₃ above/under the reflective film. For example, the pixel electrode 211 may have a multi-layered structure including ITO/Ag/ITO.

A pixel defining film 118, which includes an opening 118OP exposing a center portion of the pixel electrode 211, may be disposed on the pixel electrode 211. The pixel defining film 118 may include an organic insulating material and/or an inorganic insulating material. The opening 118OP may define an emission area (hereinafter referred to as an emission area EA) of light emitted from the organic light-emitting diode OLED. For example, a width of the opening 118OP may correspond to a width of the emission area EA.

The intermediate layer 212 may be disposed in the opening 1180P and on the pixel defining film 118. The intermediate layer 212 may include an emission layer 212b arranged in the opening 118OP of the pixel defining film 118. The emission layer 212b may include a high-molecular organic material or a low-molecular organic material for emitting light of a desired color (e.g., a certain or predetermined color).

A first function layer 212a and a second function layer 212c may be arranged under and over the emission layer 212b, respectively. The first function layer 212a may include, for example, a hole transport layer (HTL), or may include an HTL and a hole injection layer (HIL). The second function layer 212c is a component disposed over the emission layer 212b, and is optionally provided. The second function layer 212c may include an electron transport layer (ETL) and/or an electron injection layer (EIL). Like the counter electrode 213 described in more detail below, the first function layer 212a and/or the second function layer 212c may be common layers formed to entirely cover the substrate 100.

The counter electrode 213 may include a conductive material having a small work function. For example, the counter electrode 213 may include a (semi) transparent layer including Ag, Mg, Al, Pt, Pd, Au, Ni, Nd, Ir, Cr, Li, Ca, or suitable alloys thereof. As another example, the counter electrode 213 may further include a layer such as ITO, IZO, ZnO, or In₂O₃ on the (semi) transparent layer including one or more of the aforementioned materials.

In some embodiments, a capping layer may be further disposed on the counter electrode 213. The capping layer may include LiF, an inorganic material, and/or an organic material.

The thin-film encapsulation layer TFE may cover the organic light-emitting diode OLED. In other words, the thin-film encapsulation layer TFE may be disposed on the counter electrode 213. In an embodiment, the thin-film encapsulation layer TFE may include at least one inorganic encapsulation layer, and at least one organic encapsulation layer. In an embodiment, as illustrated in FIG. 4, the thin-film encapsulation layer TFE includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may include at least one inorganic material from among Al₂O₃, TiO₂, Ta₂O₅, HfO₂, ZnO₂, SiO₂, SiNₓ, or SiON. The organic encapsulation layer 320 may include a polymer-based material. The polymer-based material may include an acryl-based resin, an epoxy-based resin, polyimide, polyethylene, and/or the like. In an embodiment, the organic encapsulation layer 320 may include acrylate.

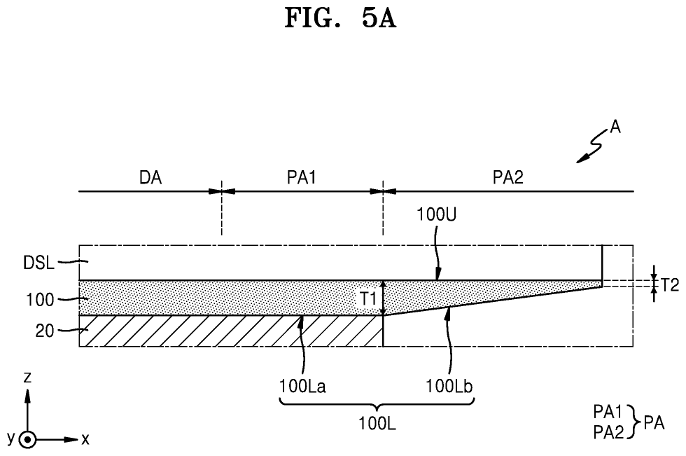

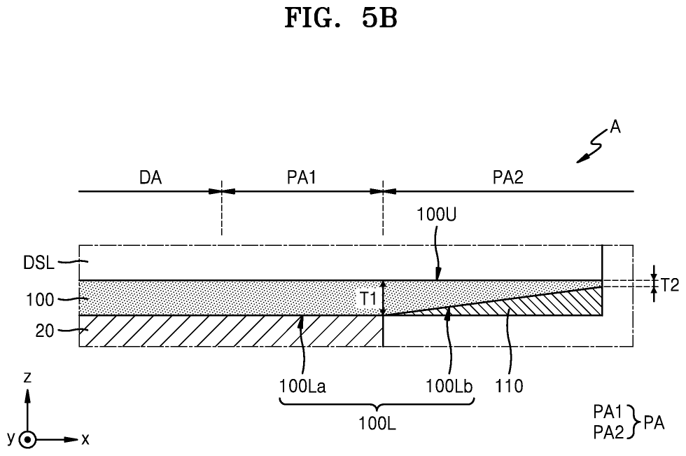

FIG. 5A is an enlarged view of the area A shown in FIG. 3, according to an embodiment. The shape of the substrate 100 shown in FIG. 5A corresponding to the region A may also be applied to other areas of the substrate 100 that are arranged in the peripheral area PA.

Referring to FIG. 5A, the peripheral area PA of the substrate 100 may include a first peripheral area PA1 overlapping with the cover panel 20, and a second peripheral area PA2 arranged outside the first peripheral area PA1. The second peripheral area PA2 may include an area of the substrate 100 that does not overlap with the cover panel 20, and is exposed from (e.g., out of) the cover panel 20.

In the second peripheral area PA2, the substrate 100 may have a shape in which a thickness (e.g., in the z direction) of the substrate 100 decreases in a direction (e.g., in the x direction or the y direction) from the first peripheral area PA1 toward the second peripheral area PA2. For example, in the second peripheral area PA2 adjacent to the first peripheral area PA1, a thickness T1 of the substrate 100 may be greater than a thickness T2 of an end portion of the substrate 100. The end portion of the substrate 100 may be arranged in the second peripheral area PA2. In an embodiment, the thickness of the substrate 100 may gradually decrease at least in the second peripheral area PA2. Because the substrate 100 in the peripheral area PA has the shape in which the thickness of the substrate 100 decreases toward an edge of the substrate 100, damage to the display apparatus 1 due to external pressure may be reduced, and reliability of the display apparatus 1 may be improved. In an embodiment, the thickness of the substrate 100 may be constant or substantially constant in the display area DA and the first peripheral area PA1.

The substrate 100 may include the first surface 100L facing a surface of the cover panel 20, and the second surface 100U facing a surface of the display layer DSL. The first surface 100L of the substrate 100 may be referred to the lower surface of the substrate 100. The second surface 100U of the substrate 100 may be referred to as the upper surface of the substrate 100.

The first surface 100L of the substrate 100 may include a 1-1 surface 100La and a 1-2 surface 100Lb having different gradients from each other with respect to an xy plane. The gradient of the 1-1 surface 100La of the substrate 100 with respect to the xy plane may be less than the gradient of the 1-2 surface 100Lb with respect to the xy plane. For example, the 1-1 surface 100La of the substrate 100 may include a horizontal surface that is parallel to or substantially parallel to the xy plane. For example, the 1-2 surface 100Lb of the substrate 100 may include a slope inclined from the 1-1 surface 100La. In other words, the first surface 100L of the substrate 100 facing the cover panel 20 may include the 1-2 surface 100Lb that has a slope. In FIG. 5A, the 1-2 surface 100Lb of the substrate 100 is illustrated as a straight line, but the present disclosure is not limited thereto. For example, in a cross-sectional view, the 1-2 surface 100Lb of the substrate 100 may have a form of a straight line having a constant or substantially constant gradient, or a form of a curved line having an inconstant gradient. In other words, the 1-2 surface 100Lb of the substrate 100 may include a plane surface or a curved surface. As used in the present specification, the 1-1 surface 100La may be referred to as a horizontal surface, and the 1-2 surface 100Lb may be referred to as a slope (or a sloped surface).

In the display area DA and the peripheral area PA, the second surface 100U of the substrate 100 may be parallel to or substantially parallel to the xy plane. The 1-1 surface 100La of the substrate 100 may be parallel to or substantially parallel to the second surface 100U of the substrate 100. The 1-2 surface 100Lb of the substrate 100 may be inclined with respect to the second surface 100U of the substrate 100. In an embodiment, in the second peripheral area PA2, the first surface 100L of the substrate 100 may be inclined with respect to the second surface 100U of the substrate 100.

The first surface 100L of the substrate 100 may include the 1-2 surface 100Lb that is the slope having a gradient at least in the second peripheral area PA2. In an embodiment, the 1-1 surface 100La of the substrate 100, which is the horizontal surface, may be arranged in the display area DA and the first peripheral area PA1, and the 1-2 surface 100Lb of the substrate 100, which is the slope, may be arranged in the second peripheral area PA2.

In an embodiment, in the display area DA, a distance between the first surface 100L and the second surface 100U of the substrate 100 may be constant or substantially constant. In an embodiment, in the display area DA, a distance between the 1-1 surface 100La and the second surface 100U of the substrate 100 may be constant or substantially constant. In an embodiment, in the first peripheral area PA1, a distance between the first surface 100L and the second surface 100U of the substrate 100 may be constant or substantially constant. In an embodiment, in the first peripheral area PA1, a distance between the 1-1 surface 100La and the second surface 100U of the substrate 100 may be constant or substantially constant. In an embodiment, in the second peripheral area PA2, a distance between the first surface 100L and the second surface 100U of the substrate 100 may decrease in the direction from the first peripheral area PA1 toward the second peripheral area PA2. In an embodiment, in the second peripheral area PA2, a distance between the 1-2 surface 100Lb and the second surface 100U of the substrate 100 may decrease in the direction from the first peripheral area PA1 toward the second peripheral area PA2.

FIG. 5B is an enlarged view of the area A shown in FIG. 3, according to an embodiment. FIG. 5B, which illustrates a modified embodiment based on the embodiment shown in FIG. 5A, illustrates that the display apparatus 1 shown in FIG. 5A further includes an organic layer 110 disposed on the substrate 100. As such, redundant description with those described above with reference to FIG. 5A may not be repeated, and the differences in FIG. 5B may be mainly described hereinafter.

Referring to FIG. 5B, the display apparatus 1 may further include the organic layer 110 disposed on the first surface 100L of the substrate 100. The organic layer 110 may be disposed on the 1-2 surface 100Lb to cover the 1-2 surface 100Lb of the substrate 100 that is the slope (e.g., the sloped surface). In an embodiment, the organic layer 110 may be arranged in the second peripheral area PA2 in which the 1-2 surface 100Lb of the substrate 100 is arranged. In other words, the organic layer 110 may be disposed on the first surface 100L of the substrate 100 that is exposed out of the cover panel 20 where the cover panel 20 and the substrate 100 do not overlap with each other. The organic layer 110 may include, for example, an organic material having a rigidity less than a rigidity of the substrate 100. In other words, the organic layer 110 may be more flexible than the substrate 100. The organic layer 110 may have a refractive index similar to (or the same or substantially the same as) a refractive index of the substrate 100.

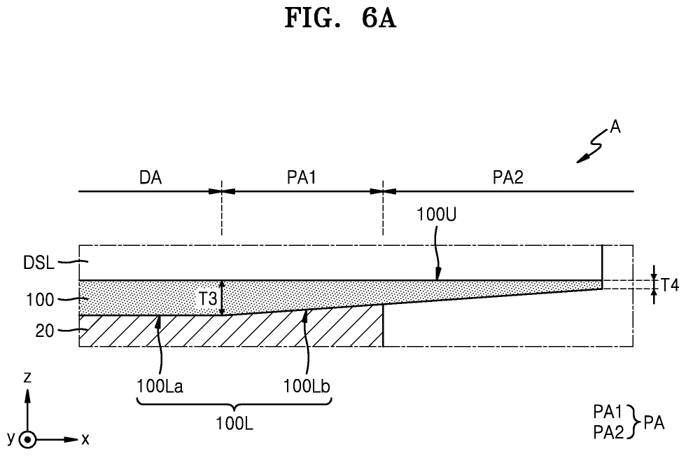

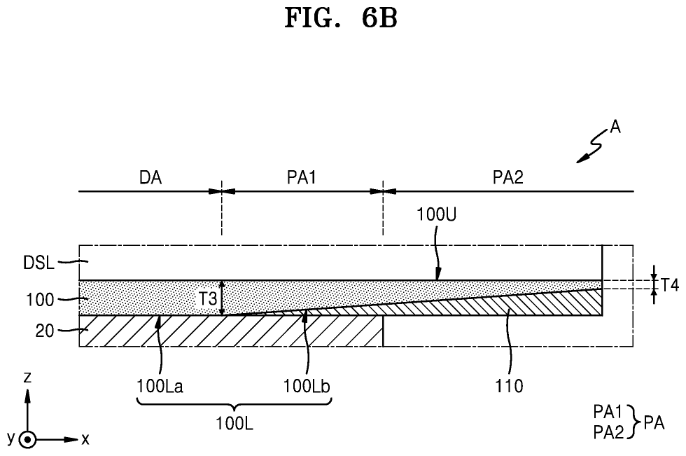

FIG. 6A is an enlarged view of the area A shown in FIG. 3, according to an embodiment. FIG. 6B is an enlarged view of the area A shown in FIG. 3, according to an embodiment. FIG. 6B may illustrate a modified embodiment based on the embodiment shown in FIG. 6A, in which the display apparatus 1 shown in FIG. 6A further includes an organic layer 110 disposed on the substrate 100. Redundant description of FIGS. 6A and 6B with those described above may not be repeated, and the differences in FIGS. 6A and 6B may be mainly described hereinafter.

Referring to FIG. 6A, in the first peripheral area PA1 and the second peripheral area PA2, the substrate 100 may have a form in which the thickness of the substrate 100 decreases in the direction from the first peripheral area PA1 toward the second peripheral area PA2. For example, in the first peripheral area PA1 adjacent to the display area DA, a thickness T3 of the substrate 100 may be greater than a thickness T4 of the end portion of the substrate 100 in the second peripheral area PA2. For example, the thickness of the substrate 100 in the first peripheral area PA1 may be greater than the thickness of the substrate 100 in the second peripheral area PA2. In an embodiment, the thickness of the substrate 100 may gradually decrease in the first peripheral area PA1 and the second peripheral area PA2. In an embodiment, the thickness of the substrate 100 may be constant or substantially constant in the display area DA.

The first surface 100L of the substrate 100 may include, in the first peripheral area PA1 and the second peripheral area PA2, the 1-2 surface 100Lb that is the slope (e.g., the sloped surface) having a gradient. In an embodiment, the 1-2 surface 100Lb of the substrate 100 may be arranged in at least a portion of the first peripheral area PA1, and may extend toward the second peripheral area PA2. In an embodiment, the 1-1 surface 100La of the substrate 100 may be arranged in the display area DA, and the 1-2 surface 100Lb of the substrate 100 may be arranged in at least a portion of the first peripheral area PA1 and the second peripheral area PA2.

In an embodiment, in the display area DA, the distance between the first surface 100L and the second surface 100U of the substrate 100 may be constant or substantially constant. In an embodiment, in the display area DA, the distance between the 1-1 surface 100La and the second surface 100U of the substrate 100 may be constant or substantially constant. In an embodiment, in at least a portion of the first peripheral area PA1, the distance between the first surface 100L and the second surface 100U of the substrate 100 may decrease in the direction from the first peripheral area PA1 toward the second peripheral area PA2. In an embodiment, in at least a portion of the first peripheral area PA1, the distance between the 1-2 surface 100Lb and the second surface 100U of the substrate 100 may decrease in the direction from the first peripheral area PA1 toward the second peripheral area PA2. In an embodiment, in the second peripheral area PA2, the distance between the first surface 100L and the second surface 100U of the substrate 100 may decrease in the direction from the first peripheral area PA1 toward the second peripheral area PA2. In an embodiment, in the second peripheral area PA2, the distance between the 1-2 surface 100Lb and the second surface 100U of the substrate 100 may decrease in the direction from the first peripheral area PA1 toward the second peripheral area PA2.

Although FIG. 6A illustrates that the thickness of the substrate 100 decreases in an entire area of the first peripheral area PA1, the present disclosure is not limited thereto. For example, the thickness of the substrate 100 may be constant or substantially constant in a portion of the first peripheral area PA1, and in another portion of the first peripheral area PA1, the thickness of the substrate 100 may decrease in the direction from the first peripheral area PA1 toward the second peripheral area PA2. In other words, in a portion of the first peripheral area PA1, the distance between the first surface 100L and the second surface 100U of the substrate 100 may be constant or substantially constant, and in another portion of the first peripheral area PA1, the distance of the first surface 100L of the substrate 100 may decrease in the direction from the first peripheral area PA1 toward the second peripheral area PA2. In this case, the 1-1 surface 100La of the substrate 100, which is the horizontal surface, may be arranged in the display area DA and a portion of the first peripheral area PA1, and the 1-2 surface 100Lb of the substrate 100, which is the slope (e.g., the sloped surface), may be arranged in another portion of the first peripheral area PA1 and the second peripheral area PA2.

Referring to FIG. 6B, the organic layer 110 may be disposed on the 1-2 surface 100Lb to cover the 1-2 surface 100Lb of the substrate 100, which is the slope (e.g., the sloped surface). The organic layer 110 may be arranged in the first peripheral area PA1 and the second peripheral area PA2 in which the 1-2 surface 100Lb of the substrate 100 is arranged. The organic layer 110 may be arranged in the first peripheral area PA1, and may extend to the second peripheral area PA2. In the first peripheral area PA1, a portion of the organic layer 110 may be arranged between the substrate 100 and the cover panel 20. Another portion of the organic layer 110 may be arranged in the second peripheral area PA2.

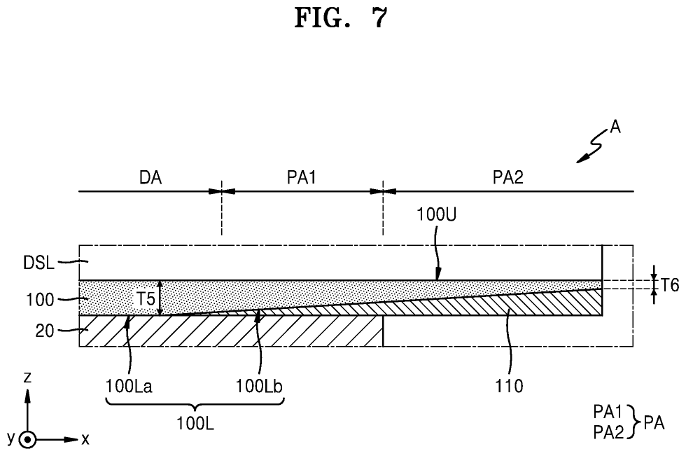

FIG. 7 is an enlarged view of the area A shown in FIG. 3, according to an embodiment. Redundant description of FIG. 7 as those above with reference to FIGS. 5A and 5B may not be repeated, and the differences in FIG. 7 may be mainly described hereinafter.

Referring to FIG. 7, the display apparatus 1 may include the organic layer disposed between the substrate 100 and the cover panel 20. In this case, in a portion of an edge of the display area DA, the substrate 100 may have a form in which the thickness of the substrate 100 decreases in the direction from the display area DA toward the peripheral area PA. In other words, in a portion of the display area DA, the first peripheral area PA1, and the second peripheral area PA2, the substrate 100 may have the form in which the thickness of the substrate 100 decreases in the direction from the display area DA toward the peripheral area PA. For example, in the display area DA, a thickness T5 of the substrate 100 may be greater than a thickness T6 of the end portion of the substrate 100. For example, the thickness T5 of the substrate 100 in the display area DA may be greater than the thickness of the substrate 100 in the first peripheral area PA1 and the thickness of the substrate 100 in the second peripheral area PA2. For example, the thickness of the substrate 100 in the first peripheral area PA1 may be greater than the thickness of the substrate 100 in the second peripheral area PA2. In an embodiment, the thickness of the substrate 100 may gradually decrease in the direction from the display area DA toward the peripheral area PA.

In a portion of the display area DA, the first peripheral area PA1, and the second peripheral area PA2, the first surface 100L of the substrate 100 may include the 1-2 surface 100Lb that is a slope (e.g., a sloped surface) having a gradient. In an embodiment, the 1-2 surface 100Lb of the substrate 100, which is the slope, may be arranged in the display area DA adjacent to the peripheral area PA, and may extend to the first peripheral area PA1 and the second peripheral area PA2. In an embodiment, the 1-1 surface 100La of the substrate 100, which is the horizontal surface, may be arranged in a portion of the display area DA, and the 1-2 surface 100Lb of the substrate 100, which is the slope, may be arranged another portion of the display area DA, the first peripheral area PA1, and the second peripheral area PA2.

In an embodiment, in a portion of the display area DA, the distance between the first surface 100L and the second surface 100U of the substrate 100 may be constant or substantially constant. In an embodiment, in a portion of the display area DA, the distance between the 1-1 surface 100La and the second surface 100U of the substrate 100 may be constant or substantially constant. In an embodiment, in another portion of the display area DA, the distance between the first surface 100L and the second surface 100U of the substrate 100 may decrease in the direction from the display area DA toward the peripheral area PA. In an embodiment, in the other portion of the display area DA, the distance between the 1-2 surface 100Lb and the second surface 100U of the substrate 100 may decrease in the direction from the display area DA toward the peripheral area PA.

In an embodiment, in the first peripheral area PA1, the distance between the first surface 100L and the second surface 100U of the substrate 100 may decrease in the direction from the first peripheral area PA1 toward the second peripheral area PA2. In an embodiment, in the first peripheral area PA1, the distance between the 1-2 surface 100Lb and the second surface 100U of the substrate 100 may decrease in the direction from the first peripheral area PA1 toward the second peripheral area PA2. In an embodiment, in the second peripheral area PA2, a distance between the first surface 100L of the substrate 100 and the second surface 100U of the substrate 100 may decrease in the direction from the first peripheral area PA1 toward the second peripheral area PA2. In an embodiment, in the second peripheral area PA2, a distance between the 1-2 surface 100Lb of the substrate 100 and the second surface 100U of the substrate 100 may decrease in the direction from the first peripheral area PA1 toward the second peripheral area PA2.

The organic layer 110 may be disposed on the 1-2 surface 100Lb to cover the 1-2 surface 100Lb of the substrate 100, which is the slope (e.g., the sloped surface). The organic layer 110 may be arranged in a portion of the display area DA adjacent to the peripheral area PA in which the 1-2 surface 100Lb of the substrate 100 is arranged, the first peripheral area PA1, and the second peripheral area PA2. The organic layer 110 may be arranged in the portion of the display area DA adjacent to the peripheral area PA, and may extend to the first peripheral area PA1 and the second peripheral area PA2. A portion of the organic layer 110 may be disposed between the substrate 100 and the cover panel 20, in the portion of the display area DA adjacent to the peripheral area PA and the first peripheral area PA1. Another portion of the organic layer 110 may be arranged in the second peripheral area PA2.

According to one or more embodiments of the present disclosure, damage that may be caused due to an external pressure may be prevented or substantially prevented as the display apparatus includes the substrate having a relatively smaller thickness in the peripheral area. Accordingly, reliability of the display apparatus may be improved. However, the aspects and features of the present disclosure are not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a cover panel;
a display panel on the cover panel; and
a cover window on the display panel,
wherein the display panel comprises:
a substrate having a first surface facing the cover panel, and a second surface opposite to the first surface, the substrate comprising:
a display area comprising a plurality of pixels;
a first peripheral area outside the display area, and overlapping with the cover panel; and
a second peripheral area outside the first peripheral area;
a display layer on the second surface of the substrate, and comprising a pixel circuit; and
a thin-film encapsulation layer on the display layer, and
wherein the first surface of the substrate comprises:
a 1-1 surface parallel to the second surface; and
a 1-2 surface inclined from the 1-1 surface and located at least in the second peripheral area.

2. The display apparatus of claim 1, wherein a width of the substrate is greater than a width of the cover panel.

3. The display apparatus of claim 1, wherein the second peripheral area does not overlap with the cover panel.

4. The display apparatus of claim 1, wherein, in the second peripheral area, a distance between the first surface and the second surface of the substrate decreases in a direction from the first peripheral area toward the second peripheral area.

5. The display apparatus of claim 4, wherein the 1-1 surface of the substrate is located in the display area and the first peripheral area.

6. The display apparatus of claim 1, wherein the 1-2 surface of the substrate is located in at least a portion of the first peripheral area and the second peripheral area.

7. The display apparatus of claim 6, wherein, in at least the portion of the first peripheral area, a distance between the first surface and the second surface of the substrate decreases in a direction from the first peripheral area toward the second peripheral area.

8. The display apparatus of claim 6, wherein the 1-1 surface of the substrate is located in the display area.

9. The display apparatus of claim 6, wherein, in at least the portion of the first peripheral area, a distance between the first surface and the second surface of the substrate decreases in a direction from the first peripheral area toward the second peripheral area, and in another portion of the first peripheral area, the distance between the first surface and the second surface of the substrate is constant.

10. The display apparatus of claim 1, further comprising an organic layer on the 1-2 surface of the substrate.

11. The display apparatus of claim 10, wherein the organic layer comprises a material having a rigidity less than a rigidity of the substrate.

12. The display apparatus of claim 1, wherein a width of the substrate is less than a width of the cover window.

13. The display apparatus of claim 1, wherein the cover panel comprises a heat-radiating layer.

14. The display apparatus of claim 1, further comprising:
an optical function layer on the display panel; and
a touch sensor layer on the optical function layer.

15. A display apparatus comprising:
a cover panel; and
a display panel on the cover panel,
wherein the display panel comprises:
a substrate having a first surface facing the cover panel, and a second surface opposite to the first surface, the substrate comprising:
a display area including a plurality of pixels; and
a peripheral area outside the display area;
a display layer on the second surface of the substrate, and comprising a pixel circuit; and
a thin-film encapsulation layer on the display layer,
wherein a width of the substrate is greater than a width of the cover panel, and
wherein at least a portion of the first surface of the substrate has a slope in the peripheral area.

16. The display apparatus of claim 15, wherein the peripheral area comprises:
a first peripheral area overlapping with the cover panel; and
a second peripheral area outside the first peripheral area, and
wherein the slope of the substrate is located in at least the second peripheral area.

17. The display apparatus of claim 16, wherein the slope of the substrate is located in the first peripheral area, and extends to the second peripheral area.

18. The display apparatus of claim 15, further comprising an organic layer on the slope of the substrate.

19. The display apparatus of claim 18, wherein the organic layer comprises a material having a rigidity less than a rigidity of the substrate.

20. A display apparatus comprising:
a cover panel;
a display panel on the cover panel; and
a cover window on the display panel,
wherein the display panel comprises:
a substrate comprising:
a display area comprising a plurality of pixels;
a first peripheral area outside the display area, and overlapping with the cover panel; and
a second peripheral area outside the first peripheral area;
a display layer on the substrate, and comprising a pixel circuit; and
a thin-film encapsulation layer on the display layer, and
wherein, in the second peripheral area, a thickness of the substrate decreases in a direction from the first peripheral area toward the second peripheral area.

21. The display apparatus of claim 20, wherein the substrate comprises a first surface facing the cover panel, and a second surface opposite the first surface, and
wherein, in the second peripheral area, the first surface of the substrate is inclined with respect to the second surface.

22. The display apparatus of claim 20, wherein, in the first peripheral area, a thickness of the substrate is constant.

23. The display apparatus of claim 20, wherein, in at least a portion of the first peripheral area, a thickness of the substrate decreases in the direction from the first peripheral area toward the second peripheral area.
